(19) United States
(12) Patent Application Publication
(10) Pub. No.: US 2023/0134296 A1
(43) Pub. Date: May 4, 2023

(54) Transformer Isolator Having RF Shield Structure for Effective Magnetic Power Transfer

(71) Applicant: Lam Research Corporation, Fremont, CA (US)

(72) Inventors: Neil M.P. Benjamin, Palo Alto, CA (US); Hema Swaroop Mopidevi, Fremont, CA (US); John Pease, San Mateo, CA (US)

(21) Appl. No.: 17/918,538

(22) PCT Filed: Mar. 23, 2021
(86) PCT No.: PCT/US21/23670

§ 371 Date: Oct. 12, 2022

(51) Int. Cl. H01F 27/36; H01F 27/24; H01F 27/28; H01J 37/32

(52) U.S. Cl. CPC H01F 27/363; H01F 27/24; H01F 27/28; H01J 37/32724; H01J 2237/2007; H01J 37/32183

(57) ABSTRACT

An apparatus for a transformer isolator used for transferring power to an element of a substrate support used in a plasma chamber is provided. A primary of the transformer isolator includes a primary base plate configured to electrically couple to ground. A primary ferrite disposed over the primary base plate, and the primary ferrite has a primary circular channel. A primary coil is wound within the primary circular channel. A primary shield is disposed over the primary ferrite and the primary coil. The primary shield includes a first plurality of radial segments that extend from a primary center region to outside a periphery of the primary ferrite. An extended region of the primary shield has a curved section to connect the primary shield with the primary base plate. In one example, the secondary of the transformer isolator has similar construction as the primary and are used together as part of the transformer isolator.

### FIELD OF EMBODIMENTS

The present embodiments relate to an isolation transformer having shielding structures that improve magnetic power transfer and provide isolation from electrostatic field currents.

### RELATED ART

Plasma has long been employed to process substrates (e.g., wafers) into semiconductor products, such as integrated circuits. In many modern plasma processing systems, a substrate may be placed onto an RF chuck for plasma processing inside a plasma processing chamber. The RF chuck may be biased with an RF signal, using RF voltages in the range from tens to thousands of volts and RF frequencies in the range from tens of KHz to hundreds of MHz. Since the RF chuck also acts as a substrate support, proper control of the RF chuck temperature is an important consideration to ensure repeatable process results.

Generally speaking, the RF chuck's temperature is maintained by one or more electric heaters, which may be integrated or coupled within the substrate support. Electrical power to the electric heater is typically obtained from line AC voltage via an appropriate control circuit to maintain the substrate support at a desired temperature range. By way of example, the electric heater may be powered by DC, line frequency (e.g., 50/60 Hz AC) or KHz range AC power.

Thus, the substrate support needs to be simultaneously subject to substantial levels of RF power, while also powering the heaters. AC circuitry providing power to these heaters can inadvertently draw RF power from the plasma in the chamber, resulting in loss of etch-rate, reduced power transfer to the heaters and/or damage to the AC circuitry. In an attempt to address these issues, it is common to connect filters to block electrostatic currents. These filters usually employ large LC tank circuits, e.g., using coils wound on cores to provide inductance along with capacitor banks to provide high impedance at select frequencies.

Unfortunately, traditional filters suffer from several disadvantages. One is unit to unit variability of coil windings. This variability introduces repeatability issues in the primary resonance. Also, parasitic resonances of such RF filters introduce further unpredictability.

It is in this context that embodiments of the present disclosure arise.

### SUMMARY

Broadly speaking, the embodiments described herein provide for an efficient transformer isolator. The transformer isolator implements a unique shielding configuration that is optimized for efficient power transfer from a primary to a secondary, while providing efficient isolation from currents returning from the secondary back to the primary

In one embodiment, an apparatus for a transformer isolator used for transferring power to an element of a substrate support used in a plasma chamber is provided. A primary of the transformer isolator includes a primary base plate configured to electrically couple to ground. A primary ferrite disposed over the primary base plate, and the primary ferrite has a primary circular channel A primary coil is wound within the primary circular channel. A primary shield is disposed over the primary ferrite and the primary coil. The primary shield includes a first plurality of radial segments that extend from a primary center region to outside a periphery of the primary ferrite. An extended region of the primary shield has a curved section to connect the primary shield with the primary base plate. In one example, the secondary of the transformer isolator has similar construction as the primary and are used together as part of the transformer isolator.

In another embodiment, a transformer isolator for transferring power to an element of a substrate support used in a plasma chamber is provided. A primary of the transformer isolator includes a primary base plate configured to electrically couple to a ground. A primary ferrite is disposed over the primary base plate. The primary ferrite has a primary circular channel. A primary coil is wound within the primary circular channel A primary shield is disposed over the primary ferrite and the primary coil. The primary shield includes a first plurality of radial segments that extend from a primary center region to outside a periphery of the primary ferrite and a first curved section to connect the primary shield with the primary base plate. The transformer isolator includes a secondary that has a secondary base plate configured to electrically couple to a radio frequency (RF) ground return of the plasma chamber. A secondary ferrite is disposed over the secondary base plate. The secondary ferrite has a secondary circular channel. A secondary coil is wound within the secondary circular channel of the secondary ferrite. A secondary shield is disposed over the secondary ferrite and the secondary coil. The secondary shield includes a second plurality of radial segments that extend from a secondary center region to outside a periphery of the secondary ferrite and a second curved section to connect the secondary shield with the secondary base plate. The primary shield is oriented to be spaced apart from and face the secondary shield.

In yet another embodiment, a shield structure for use in a transformer isolator is provided. The shield structure includes a dielectric substrate having a center, a substantially flat surface that radially extends from the center to a periphery, and a curved extension that extends from the periphery. A conductive pattern is formed over the dielectric substrate, and the conductive pattern forms a plurality of radial segments. Each radial segment has a plurality of slits extending over the substantially flat surface and the curved extension, and each of the plurality of radial segments includes a segment end located near the center of the dielectric substrate. The conductive pattern includes a center segment aligned with the center, and wherein select ones of the segment ends are connected to the center segment.

Other aspects of the invention will become apparent from the following detailed description, taken in conjunction with the accompanying drawings, illustrating by way of example the principles of the invention.

### BRIEF DESCRIPTION OF DRAWINGS

The present invention is illustrated by way of example, and not by way of limitation, in the figures of the accompanying drawings and in which like reference numerals refer to similar elements and in which:

FIG. 1 illustrates a system used for processing a wafer under plasma conditions, in accordance with one embodiment.

FIG. 2 provides a more detailed example of the power transfer isolator, including the transformer isolator, in accordance with one embodiment.

FIG. 3A illustrates an example transformer arrangement.

FIG. 3B illustrates a cross-sectional view of the transformer of FIG. 3A and magnetic field (H) lines.

FIG. 4 illustrates a transformer isolator, in accordance with one embodiment.

FIGS. 5A-5D illustrate examples of slits that are formed on a dielectric substrate in order to define a plurality of radial segments, in accordance with one embodiment.

FIGS. 5E-5G illustrate example patterns that can be used to construct each of the radial segments, in accordance with one embodiment.

FIG. 6A is an example of modeling that illustrates how the center region of the shields, without a center patterned cover allows leakage of currents from the secondary back to the primary, in accordance with one embodiment.

FIG. 6B illustrates one example configuration of a conductive pattern to form a center segment of conductive material, in accordance with one embodiment.

FIG. 7A illustrates one example configuration of the primary shield and the secondary shield used in a transformer isolator, in accordance with one embodiment.

FIG. 7B illustrates another example of a primary shield and a secondary shield having sides that include minimal curvature at the transition to the sides, in accordance with one embodiment.

FIG. 8 illustrates an example orientation of the slits of the primary shield 402, in accordance with one embodiment.

FIG. 9A illustrates an example of the primary shield, including the primary side that defines the extension having the curve, in accordance with one embodiment.

FIG. 9B illustrates how the primary shield has a top surface that is substantially flat and then curves at the periphery, in accordance with one embodiment.

### DETAILED DESCRIPTION

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

On etch tools, heating the electro-static chuck is one way to tune and improve process uniformity. The alternating current (AC) circuitry providing power to these heaters can inadvertently draw RF power from a chamber resulting in loss of etch-rate.

Typically, radio frequency (RF) filters are employed to block this RF power from returning to circuitry of the AC circuitry of the heater's AC/DC power supply. These filters are traditionally designed as parallel LC tanks with coils wound on cores (or air cores) to provide inductance along with capacitor banks to provide high impedance at select resonant frequencies. There are inherent disadvantages to this filtering approach as the coil windings and their associated primary and parasitic resonances have repeatability issues. In one embodiment, a transformer approach for RF filtering is believed to assist in solving some of these problems. A transformer provides a capacitive rejection response, and as there are no resonances this approach is more immune to repeatability issues.

In one configuration, the transformer's primary and secondary are separated by a physical gap to avoid RF capacitively coupling from secondary to primary, as the latter is connected to sensitive AC circuitry and/or DC circuitry. RF is inherently present at the secondary of the transformer as it is coupled in common-mode, e.g., RF ground of the chamber hardware. However, simply having a large physical gap between the primary and secondary of the transformer in order to solve the aforementioned issue would drastically reduce the efficiency of power transmission. In accordance with one embodiment, an isolation transformer is configured with RF shielding to block electromagnetic field penetration and/or electrostatic currents back to the primary, but also allow for efficient magnetic power to transfer and penetrate from the primary to the secondary for powering the heaters of the chuck. In one embodiment, to prevent loss of RF power from secondary to ground and primary circuitry, the physical gap may be between about 0.5 mm and about 30 mm and capable of standing off several kilovolts (KVs). For example, the DC voltage between the gap may be between 1 KV and 15 KVs. Thus, one purpose of physical gap between the secondary and primary is to enable RF isolation and also enable DC isolation, yet provide for efficient power transfer.

By way of example, the RF shield should not only block RF frequencies from 400 kHz to 300 MHz at 500 W to 50 kW of RF power but also allow magnetic power (0.5 kW to 50 kW) to transfer through at 100 kHz to 1 MHz switching frequencies. In one embodiment, the RF shield disclosed herein has multiple slits at multiple levels in order to minimize the eddy current dissipation which occurs when a magnetic-field couples through the shield. Generally, by incorporating slits in the RF shields; a primary shield and a secondary shield, current produced from RF power in the chamber will be directed to ground. The slits are further designed to prevent excessive circling of eddy currents that would otherwise reduce magnetic penetration and efficiency of power delivered to the heaters. Increasing the number of slits also constrains the area in which the eddy currents can loop. Reduction in eddy currents will thus increase the coupling efficiency of currents required to be induced in the coil of the secondary. Accordingly, the RF shield configuration of the present embodiments will reduce capacitive coupling to thereby block most, if not all, of the current returning from the RF power in the chamber, but also include slits that are designed to reduce eddy currents that would reduce the efficiency of magnetic penetration from the primary to the secondary.

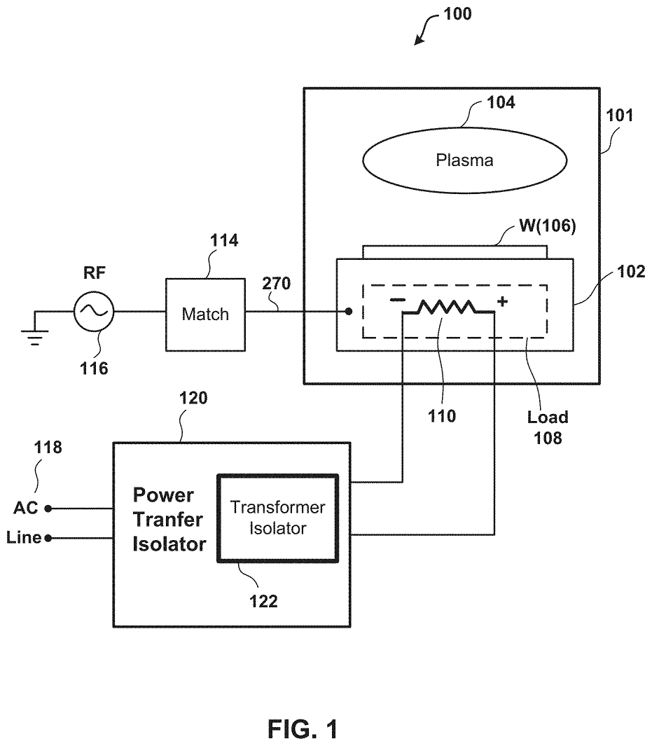

FIG. 1 illustrates a system 100 used for processing a wafer 106 under plasma conditions, in accordance with one embodiment. The system 100 is a generalized system that includes a substrate support 102, which will support the wafer 106. The substrate support 102 is shown to include a load 108 and receive power from an RF supply 116. RF supply 116 is coupled to a match 114, and the output of the match 114 delivers power over an RF delivery rod 270 that couples to the substrate support 102. Other structural features of the plasma chamber 101 are not shown, but it is understood that other structural features of the plasma chamber 101 will be included as is well known in the art. In this example, the load 108 represents a heater 110 that receives power from a power transfer isolator 120. The power transfer isolator 120 is coupled to an AC line 118. The AC line 118 is communicated through a transformer isolator 122 that delivers power to the heater 110 in the substrate support 102. Example components and circuitry used for providing a type of universal RF isolation is shown and described in US Patent RE47,276 E, reissued on Mar. 5, 2019, which is incorporated herein by reference.

In one embodiment, the transformer isolator 122 is configured to efficiently transfer power through magnetic penetration over a transformer structure having one or more RF shields, while also substantially blocking current penetration from RF power used to generate plasma in the plasma chamber 101, during processing. The heater 110 is also illustrated as a single heater, but in some embodiments multiple heaters will be incorporated into the substrate support 102. For example, some embodiments will utilize four multi-zone heaters, while other configurations will utilize an array of heaters that are individually controlled to provide strategic micro-controlled heating levels at different regions of the substrate support 102. For purposes of example, some heater arrays can include up to 150 individual heaters or more, depending on the substrate support design.

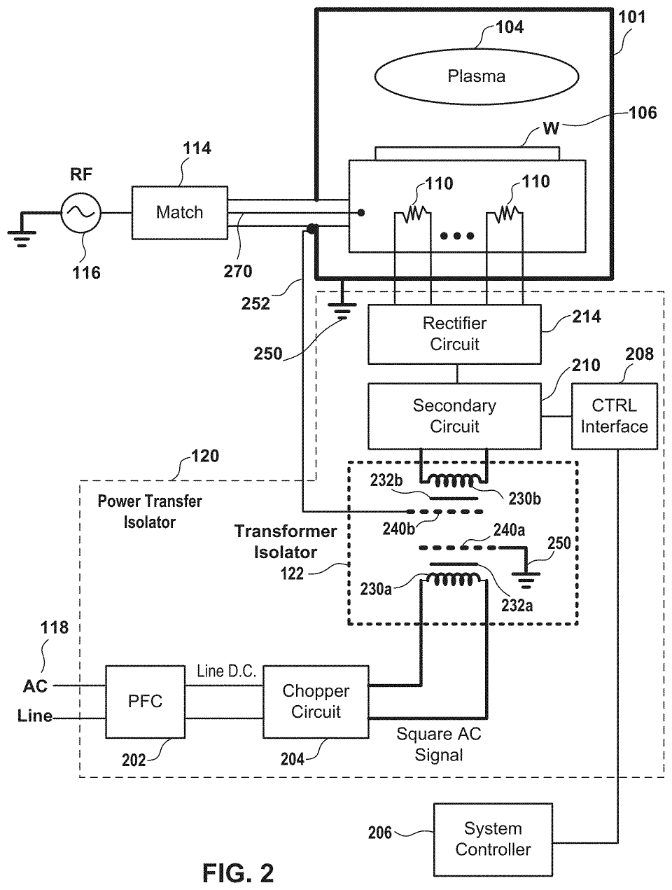

FIG. 2 provides a more detailed example of the power transfer isolator 120, including the transformer isolator 122, in accordance with one embodiment. As shown, the power transfer isolator 120 will include a power factor correction (PFC) circuit 202 that is configured to receive the AC line 118 signals and output line direct current (DC). The AC line 118 signal may be a 50 Hz or 60 Hz signal, depending on the supply. The line DC is then supplied to a chopper circuit 204. The chopper circuit 204 uses an inverter to transform the line DC to an AC signal. In one example, the AC signal output from the chopper circuit 204 produces a square AC signal at a frequency of between about 20 kHz and about 1000 kHz. In one example, the square AC signal may have a frequency of about 85 kHz. The power provided by the square AC signal may be between about 0.5 kilo-watts (kW) and about 50 kW, and in one example, about 16 kW.

The square AC signal is therefore provided to a primary coil 230a of the transformer isolator 122. As schematically shown, the primary ferrite 232a is used to contain the primary coil 230a, as will be shown in more detail below. A primary shield 240a is shown disposed over the primary coil 230a and the primary ferrite 232a. The primary shield 240a is coupled to ground 250. A secondary coil 230b, secondary ferrite 232b, and secondary shield 240b are shown oriented opposite the primary shield 240a, while maintaining a separation gap. The secondary shield 240b is shown connected to ground 250 by way of the RF ground return 252 of the plasma chamber 101.

As discussed above, when plasma 104 is generated in the plasma chamber 101, an RF return to ground from the plasma 104 moves through the ground 250, and the secondary shield 240b is connected to ground 250. The transformer isolator 122 will therefore have complementary and opposing shields that are separated by a gap, and the shields will have a slit pattern designed to reduce eddy currents and improve magnetic field transfer of power to the load (e.g., one or more heaters in the substrate support), while substantially blocking currents produce from the RF return in the plasma chamber 101.

In one example, the gap separation between the shields 240a/240b may range between about 0.5 mm and about 30 mm. This gap separation may produce a capacitance of between about 30 pico-Farads (pF) and about 100 pF. The voltage between the gap separation may be between about 0.5 kilo-volts (KV) and about 50 KV. In some embodiments, the voltage between the gap separation may be between about 1 kilo-volt (KV) and about 15 KV.

The secondary coil 230b of FIG. 2 is shown connected to secondary circuitry 210. Secondary circuitry 210 can include programming circuitry for controlling the power levels of specific heaters that are to be powered in the substrate support. A controller interface 208 can be coupled to the secondary circuitry 210, which communicates with system controller 206. System controller 206 can set the secondary circuit 210 to allow programmed values of power to be applied to each of the heaters in the substrate support in order to achieve a fine tuning of temperature across the surface of the substrate, and thus improve etch uniformity. A rectifier circuit 214 is provided and can be implemented to tune the delivery of power to specific heaters, based on control from the secondary circuit 210. The output of the rectifier circuit 214 is therefore configured to connect to one or more heaters 110 in the substrate support of the plasma chamber 101.

As mentioned above, the number of heaters will depend on the heater's configuration within the substrate support. Some substrate supports will be multi-zone substrate supports that are provided specific levels of power. Some substrate supports include arrays of heaters, which are controlled and fine-tuned depending on the process and needs for temperature variation to improve uniformity in etch operations. Lam Research Corporation, the assignee of this application implements these types of heater arrangements and are referred to as “Hydra heaters” or as a “Hydra-ESC,” and examples of such heaters can be found in U.S. Publication 2014/0220709A1, which is incorporated by reference.

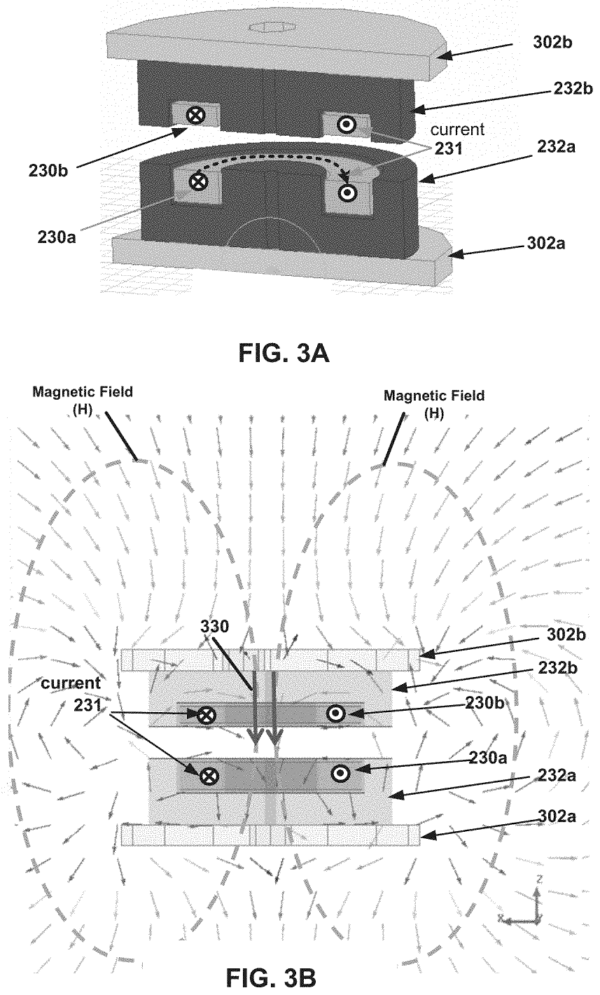

FIG. 3A illustrates an example transformer arrangement. This transformer arrangement is provided to illustrate an example construction of component parts. For the primary, components include a primary base plate 302a, a primary ferrite 232a, and a primary coil 230a. For the secondary, components include a secondary base plate 302b, a secondary ferrite 232b, and a secondary coil 230b. In this illustration, the primary is configured and arranged to face the secondary, such that the coils 230a, 230b of the primary and the secondary face each other. This illustration also indicates an example direction in which current 231 flows in the primary coil 230a and secondary coil 230b. Each of the coils 230a, 230b is, in one embodiment, wrapped in a circular configuration within a circular channel formed within the respective ferrites 232a, 232b.

In one configuration, the coils 230a, 230b are made from Litz wires. Litz wires are multi-strand wires or cables used to carry alternating current (AC) at radio frequencies. Therefore, although the primary and secondary coils 230a/b are illustrated as blocks in the graphical illustration, the coils are actually wrapped around multiple times in the channels defined in each of the primary ferrite 232a and the secondary ferrite 232b. The number of turns in each of the coils 230a, 230b will vary, depending on the voltages and ratios being transferred across the transformer.

FIG. 3B illustrates a cross-sectional view of the transformer arrangement of FIG. 3A, showing how magnetic fields (H) are produced when currents flow in the current 231 direction. These induced magnetic fields (H) show that a concentration of the magnetic field returns through the center region of the transformer arrangement and in the direction 330, based on the current 231 direction.

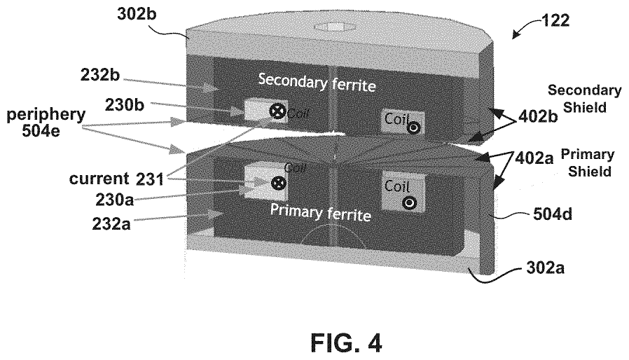

FIG. 4 illustrates a transformer isolator 122, in accordance with one embodiment. In this embodiment, a primary shield 402a is disposed over the primary ferrite 232a and the primary coil 230a. The secondary shield 402b is disposed over the secondary ferrite 232b and the secondary coil 230b. The primary shield 402a is configured to be in a facing orientation relative to the secondary shield 402b, whereby a gap separates each of the shields 402a, 402b. Also shown, the primary shield 402a extends down to connect with the primary base plate 302a. The primary shield 402a is also shown to include a plurality of slits that define radial segments extending from the center of the shield 402a/402b and out to an extended region 504d that is outside of a periphery 504e. The extended region 504d is shown to extend downward to the primary base plate 302a. The periphery 504e is shown at a diameter where the top part of the shield 402a starts to bend, turn, or curve toward one of the base plates 302a, 302b. Thus, outside of the periphery 504e of the respective shields 402a, 402b is an annular region beyond the substantially flat top surface of the respective shields 402a, 402b. It should be understood that the “substantially flat” top surface of the respective shields 402a, 402b may have surface variations, slight slopes or minor bends introduced during manufacture and/or design. The annular region is shown to bend toward the base plates 302a, 302b.

The secondary shield 402b has a similar construction, whereby the shield 402b includes a plurality of slits defining radial segments that extend from the center of the secondary shield 402b and out to the periphery before extending upward toward the secondary base plate 302b. As mentioned above, the primary base plate 302a is connected to ground, and the secondary base plate 302b is connected to ground of the plasma chamber, when the transformer isolator 122 is implemented in a configuration similar to that of FIG. 1 or FIG. 2 for delivery of power to heaters.

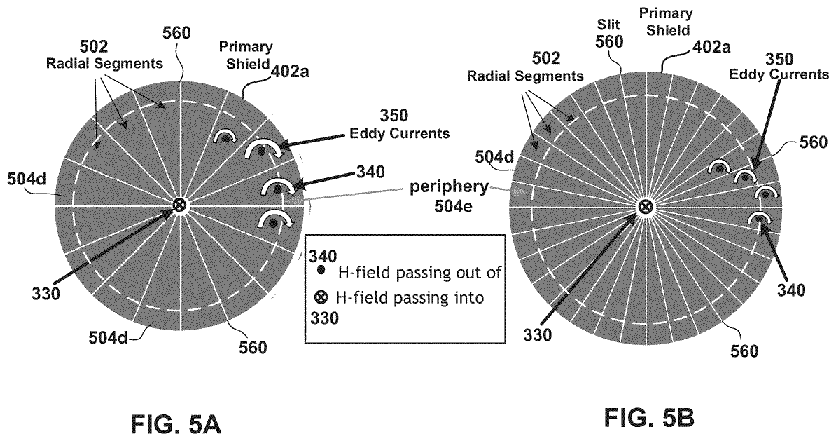

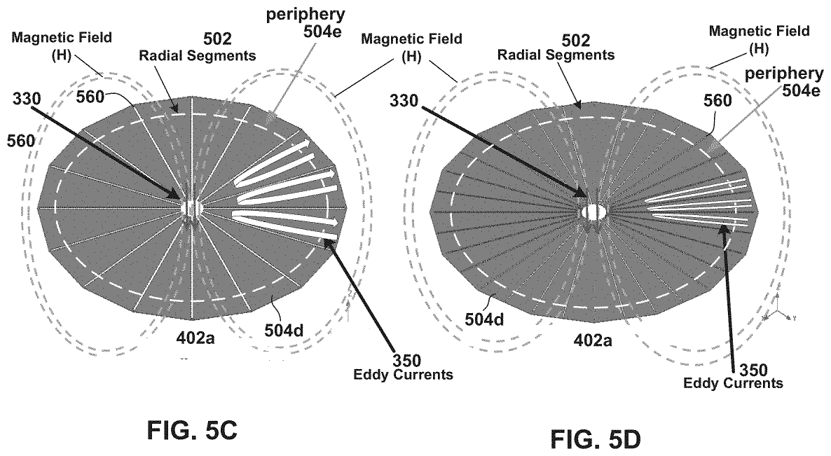

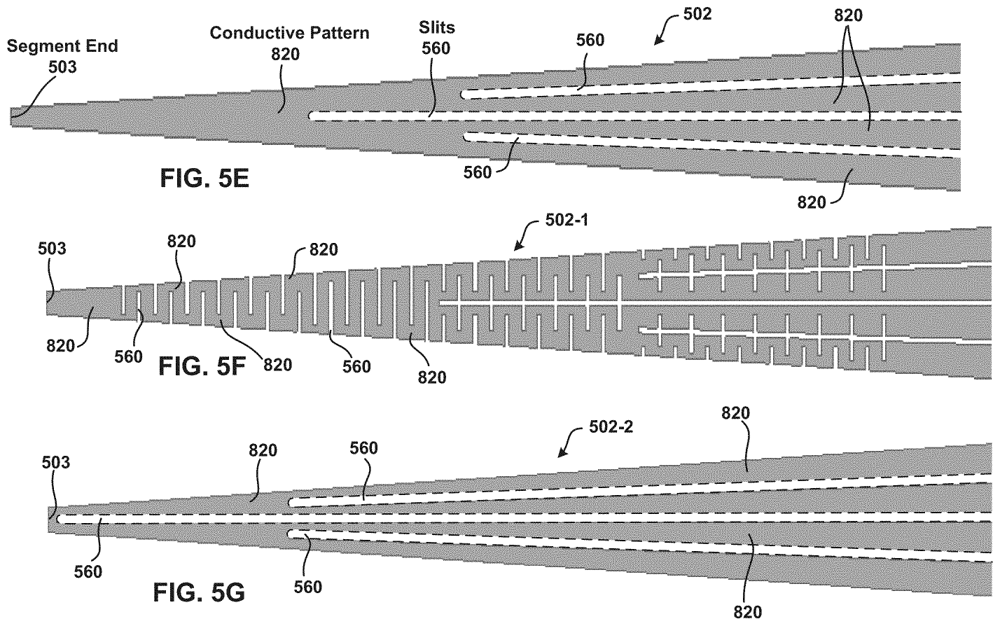

FIGS. 5A-5D illustrate examples of the slits 560 that are formed on a dielectric substrate in order to define a plurality of radial segments 502. As shown, the radial slits 560 are configured to divide the primary shield 402a and the secondary shield 402b surfaces into regions that reduce the circulation of eddy currents 350. The direction of H-fields is shown to be concentrated in the center region of the respective primary and secondary shields 402a, 402b. This is viewed as the H-field 330 passing into the primary shield 402a, and noted as “x”, and the H-field 340 passing out of the primary shield 402a is noted as “dot”. It should be understood that the H-field 340 passing out of the primary shield 402a occurs throughout the surface of the shield 402a.

Therefore, by segmenting the shields 402a, 402b with slits 560 to form radial segments 502, it is possible to reduce the circulation of the eddy currents that are generated when the H-field 340 passes through of the shields 402a, 402b. Further, because each shield 402a, 402b is extended beyond the periphery 504e that faces the opposite shield 402a, 402b, and is extended away and downward or upward toward the respective grounded base plates 302a, 302b, the power consuming effects of eddy currents can be reduced. More specifically, by creating the radial segments 502 and the extended region 504d outside of the periphery 504e that faces the respective shield 402a, 402b, the resistance of the path that the eddy currents must traverse in each radial segment 502 will increase.

As is known, power is equal to current squared times resistance. In the configurations shown in FIGS. 5A-5D, it is shown that the segments 502 are increased beyond the outer periphery 504e and extend to the respective base plates 302a, 302b, the resistance is being increased due to the increased length that the eddy currents must travel between the center of the shields 402a, 402b and grounds, as the eddy currents circle along the respective radial segments 502. Thus, the radial segments 502 and their extended regions 504d will also act to reduce power dissipation, which reduces the heat produced by the flowing eddy currents. The increased resistance paths in each of the radial segments 502 will therefore reduce current flows of the eddy currents in each of the radial segments 502. By way of example, the contribution of current to power dissipation may be more significant than that of the resistance due to the squared term.

This combination of features will allow for the maximum amount of magnetic flux to be transferred between the primary and the secondary in regions where the ferrites 232a, 232b face each other. This construction also provides for reduction in capacitive coupling, to thereby substantially block the currents flowing from the plasma to penetrate from the secondary to the primary of the transformer isolator 122. Collectively, this construction provides for efficient transfer of magnetic power between the primary to the secondary for powering the heaters of the substrate support of the plasma chamber while at the same time reducing the currents from penetrating back to the primary.

FIGS. 5E-5G illustrates example patterns that can be used to construct each of the radial segments 502. FIG. 5E illustrates how each radial segment 502 can itself have slits 560. The radial segment 502 can have a segment end 503 that is closest to a center of the respective shield 402a and 402b. Each radial segment 502 is defined over a dielectric material, where conductive patterns 820 are formed. Between the conductive patterns 820, the slits 560 remain exposing the dielectric material. As will be described below, the dielectric material is preferably defined by a single substrate where all of the radial segments 502 are patterned thereon, where the slits 560 that define the radial segments 502 and the slits 560 that are formed within radial segment 502 are also formed.

FIG. 5F illustrates an example where the conductive pattern 820 can take on any number of configurations. In some embodiments, a shield 402a or 402b, may have slits 560 that define the radial segments 502-1 as well as the slits 560 internal to the radial segments 502. Other configurations can have fewer slits or more slits, depending on the frequencies of operation, the power transfer needs, and the specific implementations of the transformer isolator 122.

The number of patterns, shapes and configurations can be chosen to fine tune and control the flow of eddy currents in the respective radial segments 502, in order to increase power transfer efficiency between the primary and secondary. That is, by reducing the eddy current flows in the shield 402a, 402b, it is possible to increase the coupling efficiency of the currents that are intended to be induced in the secondary via the primary FIG. 5G illustrates another example of a radial segment 502-2, where the conductive pattern 820 includes more slits 560 oriented toward the center of the radius of the radial segment 502. In some embodiments, it is desirable to increase the number of slits 560 closer to the center of the shield 402a, 402b, and in other embodiments it is desirable to increase the number of slits 560 in regions of the shield 402a, 402b that have more area, such as the outer diameters. By way of example, it may be desirable to reduce the number of slits 560 in the center region and increase the number of slits 560 in the outer areas to controllably reduce the flow of eddy currents and maximize the efficiency of power transfer between the primary and secondary.

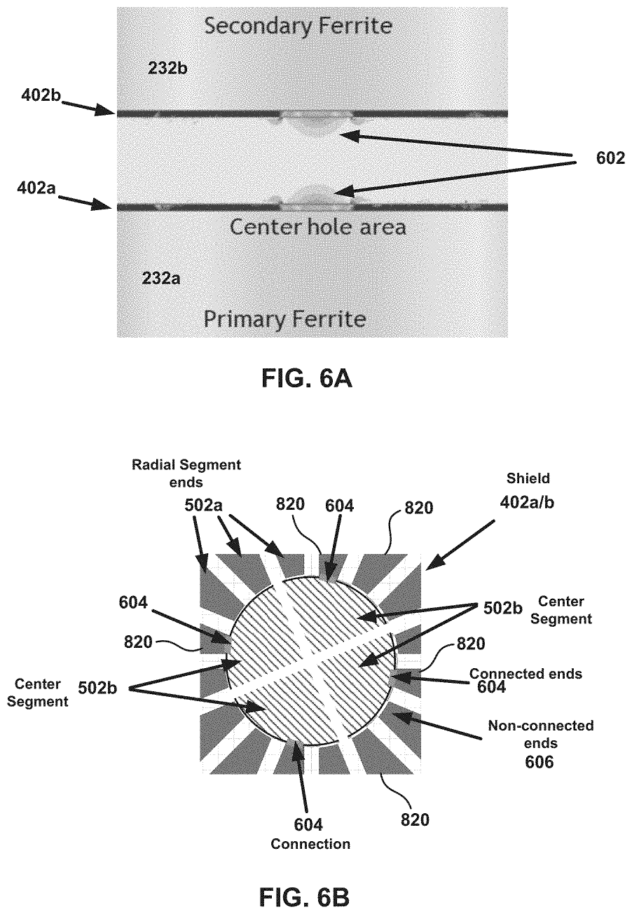

FIG. 6A is an example of modeling that illustrates how the center region of the shields 402a and 402b, if left without conductive patterning, could provide undesired direct coupling 602. In this modeling, it is believed that the slits 560 that are forming the radial segments 502 act to sufficiently block the E fields from fringing through. However, the center hole area is shown to exhibit optical transparency that could allow currents to penetrate from the secondary down to the primary Reference to a “hole,” in the context of the example refers to a lack of conductive pattern, as the shield 402a, 402b is formed from a dielectric substrate that has the conductive patterns formed thereon. As mentioned above, the transformer isolator is configured to substantially block currents from penetrating from the secondary to the primary while also efficiently allowing magnetic field penetration from the primary to the secondary to power the heaters of the substrate support.

FIG. 6B illustrates one example configuration of a conductive pattern to form a center segment 502b. The center segment 502b is shown to include four portions defined by splitting a circular conductive pattern into four. These portions are, in one embodiment, four pie portions. It should be understood that other patterns can be formed for the center segment 502b. However, in this configuration it is desired that not all of the radial segment ends 502a of the radial segments 502 should be in electrical contact with the center segment 502b. By way of example, one configuration is designed so that a connection 604 of one of the radial segment ends 502a is in electrical contact with a respective portion of the center segment 502b. As shown, there are four portions in the center segment 502b, and only one radial segment end 502a makes a connection 604 with each portion of the center segment 502b. In this manner, each portion of the center segment 502b will function as a type of extension to the radial segment 502 that has its radial segment end 502a connected therewith.

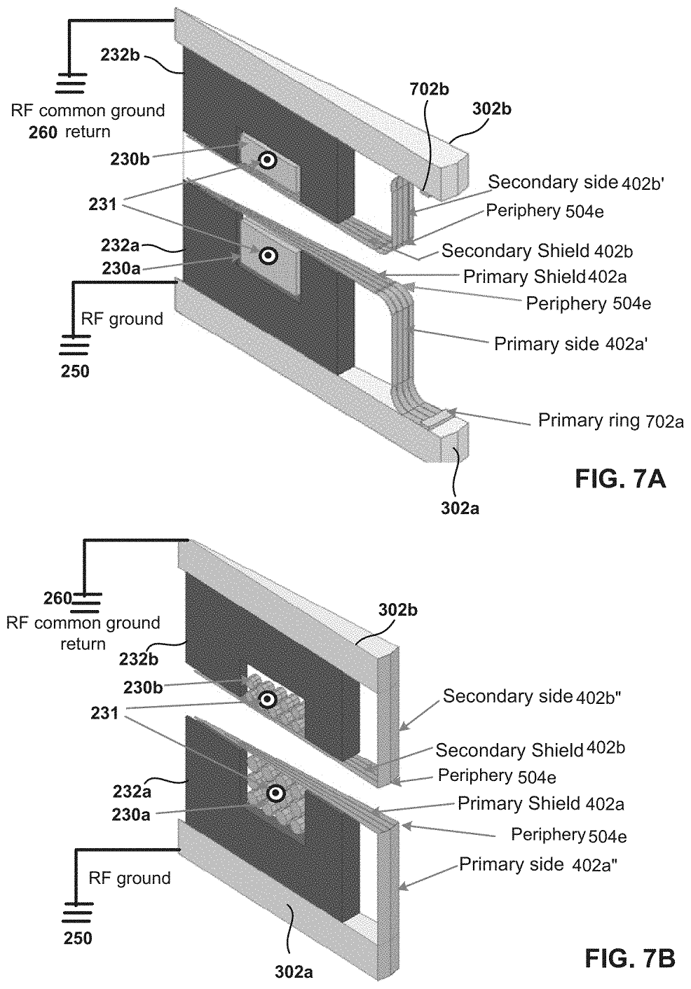

FIG. 7A illustrates one example configuration of the primary shield 402a and the secondary shield 402b used in a transformer isolator 122. In this example, each of the shields 402a and 402b has a gap-facing surface. As described herein, the gap-facing surface of each shield 402a/402b is the respective areas of the shields 402 that are oriented to face each other, e.g., from the center region to an outer region. The gap-facing surfaces that face each other are oriented to define a gap that separates the primary from the secondary. In one embodiment, the gap-facing surfaces of each of the shield 402a/402b are aligned with one another. In another embodiment, the gap-facing surfaces of each of the shield 402a/402b are not aligned with one another, e.g., there may be an offset in alignment. Further shown is the primary base plate 302a connected to AC ground 250. The secondary base plate 302b is connected to RF common ground return 260. The gap-facing surfaces of the shields 402 that face each other are configured to be substantially flat, and extend to a periphery 504e where curved sections that are void of sharp edges transition to the respective primary side 402a′ and the secondary side 402b′. As shown, the curved sections are substantially free of hard corners or edges to allow efficient flow of eddy currents in the segments.

The curved section that transitions the gap-facing surface of the primary shield 402a to the primary side 402a′ is shown to connect to the primary base plate 302a by way of a primary ring 702a. The primary ring 702a connects electrically the primary shield 402a to AC ground 250. Similarly, the curved section of the secondary shield 402b connects the gap-facing surface of the secondary shield 402b to the secondary side 402b′ which is then connected to the secondary base plate 302b via a secondary ring 702b. By incorporating the curved sections in the transition at the periphery 504e of the respective shields 402, a positive effect of reducing eddy current power dissipation is achieved. That is, the eddy currents will be allowed to efficiently traverse along the radial segments 502 from the gap-facing surfaces that face each other and gradually to the extended region of the shields 402 without causing heat buildup that would have been produced if the edges were sharp. The extended regions are shown respectively as the primary side 402a′ and secondary side 402b′.

Additionally, the extended regions of the shields 402 that include the curved sections and the sides, i.e., the primary side 402a′ and secondary side 402b′, will assist to effectively extend the length over which the eddy currents must traverse thereby increasing the resistance and reducing power dissipation. By way of example, in one eddy current simulation run at 80 kHz, it was observed that patterned radial segments 502 having the curved sections were effective to achieve an eddy current power dissipation of less than 50 watts, even considering the higher dissipation regions that align with the ferrite areas. In some areas over the slotted shield 402, the eddy current power dissipation was substantially lower, e.g., in the range of 2-20 watts. The curved sections also provide for a significantly reduced risk of arc over events and provide better stand-off to high voltages.

In some embodiments, it is possible to extend the shield 402 radially outward without including the curved sections. However, by including the curved sections, it is possible to reduce the overall diameter of the shields 402 of the transformer isolator 122 thereby reducing the capacitive coupling. Collectively, these features act to increase the efficiency of the magnetic flux transfer of power between the ferrites of the primary to the secondary, while blocking current penetration returning from the plasma chamber back to the primary.

FIG. 7B illustrates another example of a primary shield 402a and a secondary shield 402b each including a minimal curvature at the transition between the gap-facing surface and the side. For example, the primary shield 402a is shown to transition to the primary side 402a″ with a reduced curvature connection. The same is shown between the transition in the secondary shield 402b that transitions to the secondary side 402b″. This illustration is shown as an alternative embodiment, such as where a smaller diameter footprint is desired, and the frequencies and power requirements may not require as much eddy current reductions to achieve the desired operating parameters and have relaxed constraints on high-voltage standoff requirements. In one embodiment, the coils 230a, 230b are made from Litz wires, and the strands are shown by way of example in FIG. 7B. It should be understood that the coils 230a, 230b of FIG. 7A are shown as a block diagram for simplicity, but in one embodiment, are also defined by Litz wires.

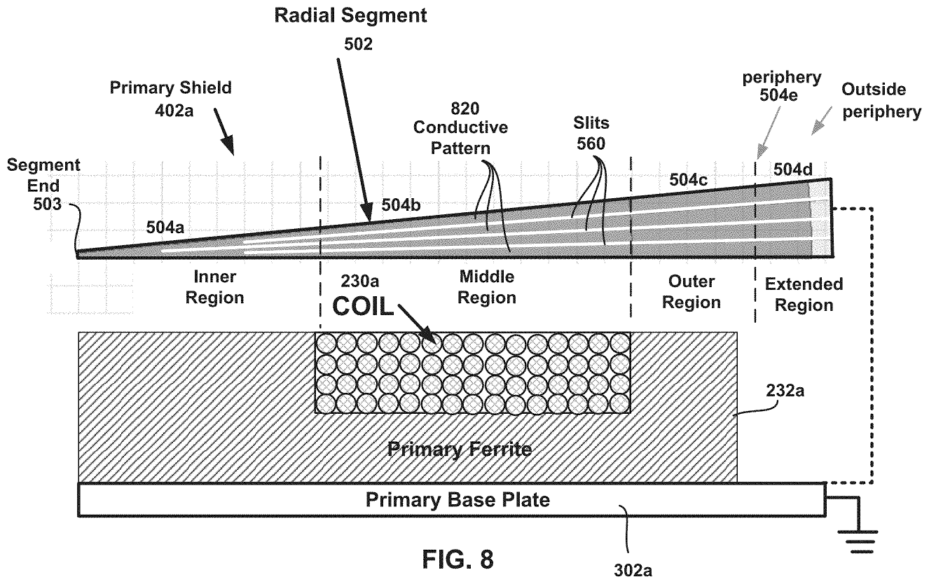

FIG. 8 illustrates an example orientation of the slits 560 of the primary shield 402a. As shown, the inner region 504a of the radial segment 502 is disposed closer to the center segment 502b of the transformer isolator 122. As discussed above with reference to FIG. 6B, the segment end 503 may be connected to the center segment 502b. The radial segment 502 includes a middle region 504b that is substantially disposed over the primary coil 230a. As shown, more slits 560 are disposed in the middle region 504b and respectively more conductive patterns 820, since more slit area is present in the middle region relative to the inner region. In the outer region 504c, the slits 560 and conductive patterns 820 are extended from the middle region 504b. In one embodiment, the conductive patterns 820 are made of copper. In other embodiments, the conductive pattern material can be silver plated copper. In another embodiment, the conductive pattern material may be aluminum. The thickness of the conductive patterns 820 are selected for efficient isolation of the RF return currents (e.g. flowing from the plasma through the secondary and back to the primary). In one embodiment, the thickness is selected based upon the skin depth that is defined for a specific operating frequency. It should be understood that the skin depth may vary for the different frequencies and the materials used for the conductive patterns 820.

The extended region 504d goes beyond the periphery 504e of the flat portion of the primary shield 402a. In one embodiment, as shown in FIG. 7A, the extended region 504d can include the curved portion and the primary side 402a′ that connects to ground. As described above, the primary coil 230a is defined by winding a Litz wire a number of times into a channel defined in the primary ferrite 232a. This description is provided for the primary, but a similar construction is provided for the secondary. In one embodiment, each of the plurality of radial segments 502 of the primary shield 402a has conductive patterns that define radial slits. The conductive patterns extend from a center and to an outer edge of the primary shield 402a so that the conductive patterns electrically connect to the primary base plate 302a that is coupled to ground.

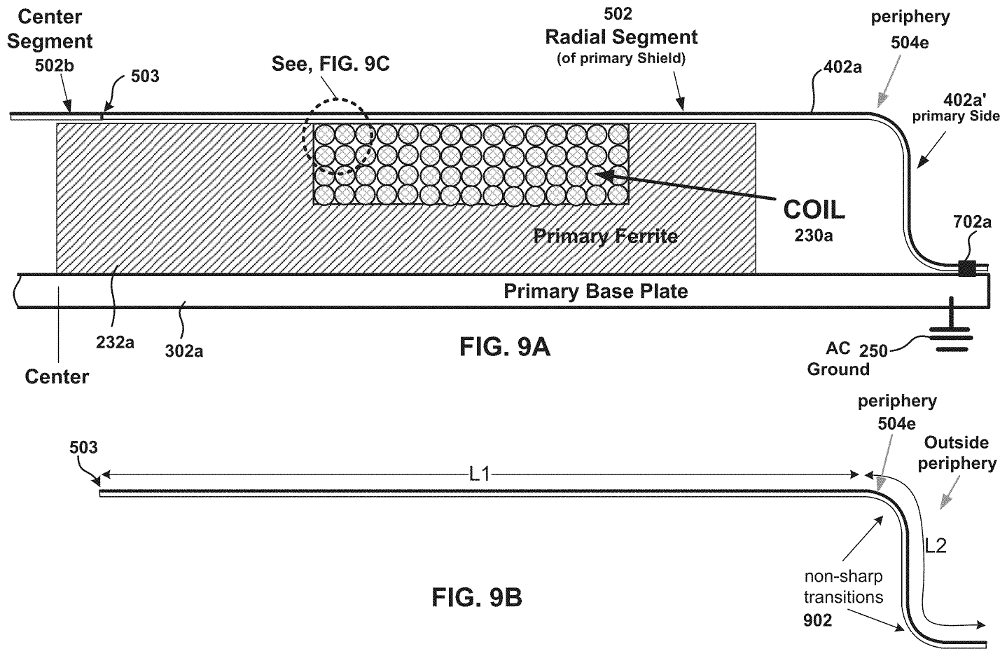

FIG. 9A illustrates an example of the primary shield 402a, including the primary side 402a′ that defines the extended region 504d. As shown, each radial segment 502 of the primary shield 402a transitions with a curvature that is void of sharp edges to the primary side 402a′. The primary side 402a′ is shown to connect with the primary ring 702a to the primary base plate 302a. In this example, the center segment 502b is connected to the segment end 503, as described in FIG. 6B where connection 604 makes the electrical connection between the respective conductive patterns of the shield. FIG. 9B illustrates how the primary shield 402a includes a top surface that is substantially flat with a length L1. The extended region 504d of the primary shield 402a extends the length over which eddy currents will traverse by an additional length L2. As described above with reference to FIG. 7A, the additional length of the radial segment 502 increases the resistance and therefore reduces the power dissipation by the eddy currents generated during operation.

In one embodiment, it is also desired that the thickness of the conductive patterns 820 should not be too much thicker than the skin depth, so that efficient magnetic penetration can be achieved from the primary to the secondary. Accordingly, there is a trade-off being made in selecting the thickness of the conductive patterns 820. On the one hand, the thickness should be enough to block current penetration returning from the plasma, while at the same time also allowing efficient magnetic penetration from the primary to the secondary to power the heaters in the substrate support of the plasma chamber. It should be understood that the skin depth may vary depending on the frequency of operation and the plasma chamber in which the transformer isolator 122 is used.

In some embodiments, the thickness of the conductive patterns 820 will be optimized in cases where there are multiple frequencies being used. By way of example, it is possible that higher frequencies, e.g., 60 MHz or higher may be used as well as lower frequencies, e.g., 400 kHz or less. In such cases, the skin depth and material being used for the conductive patterns 820 will be taken into consideration to define the appropriate conductive patterns 820 thickness that will achieve a balance of isolation from electromagnetic fields penetrating back from the plasma versus the efficiency of magnetic penetration to be transferred from the primary to the secondary. That is, it is possible to have a thickness for the conductive pattern 820 to be less than the skin depth, yet still provide for efficient isolation and efficient power transfer. In various implementations, the operating frequencies may range between 400 kHz or less to about 100 MHz.

In one embodiment, a shield structure itself is disclosed. The shield may be used on one side of a transformer (e.g., either the primary or the secondary) or on both sides as shown in the example transformer isolator 122. The shield structure includes a dielectric substrate having a circular shape that extends from a center of the circular shape to an outside diameter. In another example, the top part or gap-facing surface of the shield structure could also be square or rectangle or an n-sided polygon. The substrate has a flat surface that extends from the center to a periphery and a curved extension that extends from the periphery to the outside diameter. A conductive pattern is formed over the dielectric substrate. The conductive pattern includes a plurality of radial segments that extend over the flat surface, over the curved extension, and to the outside diameter. Each radial segment includes a plurality of slits. Each of the plurality of radial segments includes segment ends located near the center of the dielectric substrate. The conductive pattern includes a center segment, and wherein select ones of the segment ends connect to the center segment.

In some embodiments, the shield structure may be a consumable part. Over time, the shield may wear down and it may need to be replaced to maintain the transformer isolator.

Embodiments may be practiced with various computer system configurations including hand-held devices, microprocessor systems, microprocessor-based or programmable consumer electronics, minicomputers, mainframe computers and the like. The embodiments can also be practiced in distributed computing environments where tasks are performed by remote processing devices that are linked through a network.

With the above embodiments in mind, it should be understood that the embodiments can employ various computer-implemented operations involving data stored in computer systems. These operations are those requiring physical manipulation of physical quantities. Any of the operations described herein that form part of the embodiments are useful machine operations. The embodiments also relate to a device or an apparatus for performing these operations. The apparatus may be specially constructed for the required purpose, such as a special purpose computer. When defined as a special purpose computer, the computer can also perform other processing, program execution or routines that are not part of the special purpose, while still being capable of operating for the special purpose. Alternatively, the operations may be processed by a general purpose computer selectively activated or configured by one or more computer programs stored in the computer memory, cache, or obtained over a network. When data is obtained over a network the data may be processed by other computers on the network, e.g., a cloud of computing resources.

One or more embodiments can also be fabricated as computer readable code on a computer readable medium. The computer readable medium is any data storage device that can store data, which can thereafter be read by a computer system. Examples of the computer readable medium include hard drives, network attached storage (NAS), read-only memory, random-access memory, CD-ROMs, CD-Rs, CD-RWs, magnetic tapes and other optical and non-optical data storage devices. The computer readable medium can include computer readable tangible medium distributed over a network-coupled computer system so that the computer readable code is stored and executed in a distributed fashion.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

What is claimed is:

1. A transformer isolator for transferring power to an element of a substrate support used in a plasma chamber, comprising,
a primary including,
a primary base plate configured to electrically couple to a ground;
a primary ferrite disposed over the primary base plate, the primary ferrite having a primary circular channel;
a primary coil wound within the primary circular channel;
a primary shield disposed over the primary ferrite and the primary coil, the primary shield including a first plurality of radial segments that extend from a primary center region to outside a periphery of the primary ferrite and a first curved section to connect the primary shield with the primary base plate; and
a secondary including,
a secondary base plate configured to electrically couple to a radio frequency (RF) ground return of the plasma chamber;
a secondary ferrite disposed over the secondary base plate, the secondary ferrite having a secondary circular channel;
a secondary coil wound within the secondary circular channel of the secondary ferrite;
a secondary shield disposed over the secondary ferrite and the secondary coil, the secondary shield including a second plurality of radial segments that extend from a secondary center region to outside a periphery of the secondary ferrite and a second curved section to connect the secondary shield with the secondary base plate;
wherein the primary shield is oriented to be spaced apart from and face the secondary shield.

2. The transformer isolator of claim 1, wherein each of the first plurality of radial segments has a first plurality of conductive patterns that define a first plurality of radial slits extending from the primary center region to outside the periphery of the primary ferrite;
wherein each of the second plurality of radial segments has a second plurality of conductive patterns that define a second plurality of radial slits extending from the secondary center region to outside the periphery of the secondary ferrite.

3. The transformer isolator of claim 1, wherein each of the first plurality of radial segments of the primary shield and second plurality of radial segments of the secondary shield are formed from a dielectric substrate and the dielectric substrate has said conductive patterns thereon, such that the conductive patterns on the primary shield face the conductive patterns on the secondary shield.

4. The transformer isolator of claim 3, wherein the dielectric substrate of each of the primary shield and the secondary shield includes said first and second curved sections that extend outside said peripheries.

5. The transformer isolator of claim 1, wherein the primary shield and the secondary shield include corresponding center segments.

6. The transformer isolator of claim 5, wherein each center segment is defined from a dielectric substrate that has a conductive pattern.

7. The transformer isolator of claim 5, wherein each of the first and second plurality of radial segments of the primary and secondary shields extend to respective said center segments, and wherein less than all of the first and second plurality of radial segments are connected to respective said center segments.

8. The transformer isolator of claim 7, wherein each center segment includes a plurality of portions; and
wherein each portion is electrically connected to only either one of the first plurality of radial segments or one of the second plurality of radial segments.

9. The transformer isolator of claim 1, wherein the first plurality of radial segments includes a first plurality of radial slits and the second plurality of radial segments includes a second plurality of radial slits;
wherein the first and second plurality of radial slits are configured to reduce penetration of a current toward the primary and concurrently increase penetration of a magnetic field toward the secondary, wherein said current is from plasma in the plasma chamber when returning to ground and said magnetic field is used to transfer power to said element.

10. The transformer isolator of claim 1, wherein the first plurality of radial segments includes a first plurality of radial slits and the second plurality of radial segments includes a second plurality of radial slits;
wherein the first and second plurality of radial slits are configured to assist in reducing circling eddy currents and enable currents produced from plasma in the plasma chamber to flow to the ground and flow to the RF ground return.

11. The transformer isolator of claim 1, wherein the first and second curved sections are void of sharp corners or edges.

12. The transformer isolator of claim 11, wherein each of the first and second curved sections includes an upper curve and a lower curve, the upper curve transitions off of a flat region to a side region and the lower curve transitions from the side region to a connection to said ground or RF ground return.

13. The transformer isolator of claim 1, wherein the first plurality of radial segments includes a first plurality of radial slits and the second plurality of radial segments includes a second plurality of radial slits;
wherein the first and second plurality of radial slits are configured to reduce circling of eddy currents; and wherein an outer radius region of the primary shield includes more area having radial slits than an inner radius region.

14. The transformer isolator of claim 1, wherein the primary and secondary shields are formed from a dielectric substrate and include a plurality of conductive patterns disposed on the dielectric substrate;
wherein a thickness of the plurality of conductive patterns is approximately in a range of skin depth for a target operating frequency of the plasma chamber and a material type of the plurality of conductive patterns.

15. The transformer isolator of claim 1, wherein the element is a heater.

16. The transformer isolator of claim 1, wherein the primary coil is interconnected to an alternating current source and the secondary coil is interconnected to the element, wherein the transformer isolator assists in reducing capacitive coupling of RF return currents back to the alternating current source while effecting transfer power to the element via an increase in penetration of a magnetic field.

17. The transformer isolator of claim 1, wherein the primary and secondary shields are formed from a dielectric substrate and include a plurality of conductive patterns disposed on the dielectric substrate, and wherein a material type of the plurality of conductive patterns is one of copper, or silver, or aluminum, and a target operating frequency of the plasma chamber is between about 400 kHz and about 100 MHz, and wherein a thickness of the plurality of conductive patterns is set based on a skin depth associated with the material type and the target operating frequency.

18. An apparatus for a transformer isolator used for transferring power to an element of a substrate support used in a plasma chamber, a primary of the transformer isolator comprising,
a primary base plate configured to electrically couple to ground;
a primary ferrite disposed over the primary base plate, the primary ferrite having a primary circular channel;
a primary coil wound within the primary circular channel; and
a primary shield disposed over the primary ferrite and the primary coil, the primary shield including a first plurality of radial segments that extend from a primary center region to outside a periphery of the primary ferrite,
wherein an extended region of the primary shield has a curved section to connect the primary shield with the primary base plate.

19. An apparatus of claim 18, wherein the extended region increases a length of the primary shield away from the primary ferrite so that induced eddy currents reduce power dissipation in regions of the primary shield that are oriented substantially over the primary ferrite.

20. The apparatus of claim 18, wherein each of the first plurality of radial segments of the primary shield has conductive patterns that define radial slits, the conductive patterns extending from the primary center region and to an outer edge of the primary shield so that the conductive patterns electrically connect to the primary base plate that is coupled to ground.

21. The apparatus of claim 18, wherein each of the first plurality of radial segments of the primary shield are formed from a dielectric substrate and the dielectric substrate has conductive patterns thereon, the conductive patterns extend from the primary center region of the primary shield and through to the extended region the primary shield having said curved section.

22. The apparatus of claim 18, wherein the primary shield has a center segment.

23. The apparatus of claim 22, wherein the center segment has conductive center patterns and said primary shield includes conductive patterns defining said first plurality of radial segments and radial slits, wherein select ones of inner edges of said first plurality radial segments electrically connect to select ones of the conductive center patterns.

24. A shield structure for use in a transformer isolator, comprising:
a dielectric substrate having a center, a flat surface that radially extends from the center to a periphery, and a curved extension that extends from the periphery; and
a conductive pattern formed over the dielectric substrate, the conductive pattern forms a plurality of radial segments, each radial segment having a plurality of slits extending over the flat surface and the curved extension, wherein each of said plurality of radial segments includes a segment end located near the center of the dielectric substrate;
wherein the conductive pattern includes a center segment aligned with the center, and wherein select ones of the segment ends are connected to the center segment.

25. The shield structure of claim 24, wherein the curved extension does not have any sharp corners or edges.

26. The shield structure of claim 24, wherein the flat surface has a circular shape.

27. The shield structure of claim 24, wherein the center segment is defined by four pie sections.

28. The shield structure of claim 27, wherein each of the four pie sections of the center segment is connected to only one segment end.

29. The shield structure of claim 24, wherein the curved extension includes one or more curves and is configured for attachment to a ground connection for coupling said conductive pattern to ground.

30. The shield structure of claim 24, wherein the dielectric substrate is configured for placement over a ferrite and a coil when used in the transformer isolator.

31. The shield structure of claim 30, wherein the periphery is located beyond an outer edge of the ferrite.
